(19) United States
(12) Patent Application Publication
(10) Pub. No.: US 2010/0104114 A1
(43) Pub. Date: Apr. 29, 2010

(54) TIMBRAL CORRECTION OF AUDIO REPRODUCTION SYSTEMS BASED ON MEASURED DECAY TIME OR REVERBERATION TIME

(76) Inventor: Peter CHAPMAN, Lemvig (DK)

Correspondence Address: STITES & HARBISON PLLC, 1199 NORTH FAIRFAX STREET, SUITE 900, ALEXANDRIA, VA, 22314, US

(21) Appl. No.: 12/531,350

(22) PCT Filed: Mar. 17, 2008
(86) PCT No.: PCT/IB08/50988

§ 371 Date: Sep. 15, 2009

(30) Foreign Application Priority Data
Mar. 15, 2007 (DK) PA 2007 00395

(51) Int. Cl. H03G 5/00

(52) U.S. Cl. 381/103

(57) ABSTRACT

The invention relates to a method and system for use in directly adjusting the timbre of a reproduced audio signal in any closed or partially enclosed space according to the measured reverberation time or other function describing the decay of sound within the space. The measurement of the reverberation time and the correction of the timbre are performed by a system that can be incorporated within the installed audio reproduction system, although a separate measuring system could alternatively be used. The measurement of decay time or reverberation time for the space is by known methods. The invention centres around the calculation and application of a correction filter determined directly from the measured decay time or reverberation time for the space.

### TECHNICAL FIELD

The invention relates generally to the use of decay time or reverberation time of a room or other at least partially enclosed spaces for directly adjusting or correcting the timbre of sound reproduced by an audio reproduction system in this room or space and to methods and systems for use in directly adjusting or correcting the timbre of a reproduced audio signal in any at least partially enclosed room or space based on the decay time or reverberation time within the room or space.

### BACKGROUND OF THE INVENTION

When a loudspeaker is placed within an enclosed space, the timbre of the loudspeaker as perceived by a listener or listeners is affected by the acoustical properties of the space. Consequently, the timbre of a given reproduction system or loudspeaker(s) placed in different rooms with differing acoustical properties will be perceived differently—they will sound different in different rooms.

When listening to a loudspeaker in a closed space or room, the listener hears both the direct sound from the loudspeaker and also reflected sound from surfaces within the space or room. The combination of direct and reflected energy colours the timbral balance of the audio reproduction system. This coloration of the timbral balance often has a detrimental effect on the timbral balance and the perceived sound quality of the audio reproduction system.

The designer of a sound reproduction system usually wishes to give the listener the same intended listening experience regardless of the acoustical properties of the listening space. In order to compensate for differing acoustical properties of different listening spaces, knowledge of the reverberation time or another function describing the sound decay within the space is necessary.

Reverberation time is a known acoustical parameter and is a measure of the time taken for sound to decay in a space or room. Reverberation time RT, which is a function of frequency, is per definition the time required for the sound energy density to decay 60 dB. Decay time is also a measure of the time taken for sound to decay in a space or room and is a fraction of the reverberation time according to the available measuring conditions. For example, the influence of background noise may limit the available measurable decay of sound in a space or room.

### SUMMARY OF THE INVENTION

Based upon the above background, it is an objective of the present invention to provide a method and corresponding devices and systems that compensate for and reduce the detrimental effect the acoustic properties of a listening space or room have on the perceived acoustic performance of an audio reproduction system. According to a specific embodiment of the invention, the audio reproduction system itself measures the reverberation time or other function describing the sound decay within the space or room and thereafter applies appropriate correction.

Specifically—but not exclusively—the determination of the decay time or reverberation time and the adjustment or correction of the timbre are according to the invention performed by a system that is incorporated within the installed audio reproduction system and not by a separate system, but implementation of the method according to the invention could also be accomplished by a separate system. A basic feature of the invention is the calculation and application of a correction filter determined directly from the measured decay time or reverberation time for the space.

As mentioned above, reverberation time RT, which is a function of frequency, is per definition the time required for the sound energy density to decay 60 dB. In practice it is often not possible to measure sound decay over the full 60 dB dynamic range and sound decay may be measured over any other dynamic range according to for instance the signal to noise ratio obtainable in the particular situation. Thus, the measurement of reverberation time according to the above definition is not a prerequisite for the present invention and sound decay may be determined in other manners, as exemplified below in the detailed description of the invention.

The method and corresponding devices and systems according to the present invention could find use within all fields of audio reproduction in domestic and professional listening environments, where listening is performed within a closed space or room and where an audio reproduction system may be placed in spaces or rooms with differing acoustic properties.

The above and other objectives and advantages are according to a first aspect of the invention as defined by claim 1 attained by the use of a function describing the decay of acoustical energy in a room or other at least partially enclosed space as a function of time. This function will also typically be a function of frequency. Specifically a pre-determined decay time or reverberation time RT of a room or other at least partially enclosed space as a function of frequency is according to the invention used for directly adjusting or correcting the timbre of sound reproduced by a sound reproduction system in said room or other at least partially enclosed space.

The above and other objectives and advantages are according to a second aspect of the invention as defined by claim 2 attained by a method for adjusting or correcting the timbre of sound reproduced by at least one transducer, such as a loudspeaker in a room or other at least partially enclosed space, the method comprising the steps of:
determining a function describing the decay of acoustical energy such as the decay time or reverberation time RT of said room or space as a function of frequency;
based on said function, such as the decay time or reverberation time RT, determining a correction curve (filter characteristic) C as a function of frequency, where said correction curve C is a function of said function that describes the decay of acoustical energy, such as the decay time or reverberation time RT;
implementing said correction curve (filter characteristic) as an electronic filter;
processing an electrical signal via said electronic filter and providing the processed signal to one or more of said transducers and/or additional transducers.

The above and other objectives and advantages are according to a third aspect of the invention as defined by claim 8 attained by a system for adjusting or correcting the timbre of an audio signal reproduced by at least one loudspeaker in a room, the system comprising:
at least one sound source, such as a loudspeaker for emitting sound energy to said room, thereby creating a sound field in said room;
at least one sound sensitive means, such as a microphone for converting acoustical energy from said sound field in the room to electrical energy;
means for generating a test signal for emission by said at least one sound source into said room;
means for determining a function describing the decay of acoustical energy such as the decay time or reverberation time RT as a function of frequency based on said test signal and on a signal provided by said at least one sound sensitive means;
means for determining a correction curve (filter characteristic) C as a function of frequency, where said correction curve C is a function of said function that describes the decay of acoustical energy, such as the reverberation time RT or decay time;
correction filter means, the frequency response of which is determined based on said correction curve C;
   whereby said correction filter means can be used for processing an electrical signal and where the processed electrical signal is provided to one or more of said sound sources and/or additional sound sources.

According to a preferred embodiment of the present invention, a number of loudspeaker-microphone combinations are used within a space or room. The loudspeaker-microphone combinations are designed in such a way that the microphone is an integrated part of the loudspeaker's design. Furthermore, according to this embodiment active loudspeaker systems are used, where the internal signal conditioning for the loudspeaker and microphone, within the loudspeaker systems, is performed digitally. The loudspeaker systems are connected to a network enabling 2-way data communication. A master unit provides control of the system. This master unit may be a separate master unit or one of the loudspeaker-microphone combinations on the network that has been designated as the master unit.

The total number of loudspeakers can exceed the number of microphones in the audio reproduction system, in other words, loudspeakers without microphones can be included in the system but they cannot themselves provide a microphone measurement for the calculation of the decay time or reverberation time. They can however, be used to reproduce a test signal for measurement by the microphones in the audio reproduction system. A calculated correction or corrections can then be applied to some or all loudspeakers connected to the audio reproduction system.

For loudspeaker systems where the internal signal conditioning for the loudspeaker is not performed digitally, for example in the case of an analogue active loudspeaker or a passive loudspeaker system, or the loudspeaker system does not have network capabilities, the loudspeaker system can be connected to the network and thus to the said audio reproduction system by an interface that can communicate with the audio reproduction system. The interface can then initiate a test signal that can be reproduced by the said loudspeaker(s) and also apply the necessary correction or corrections.

In certain specially designed loudspeaker systems, the microphones in the loudspeaker-microphone combinations mentioned can be replaced by using the loudspeaker diaphragm(s) within the loudspeaker system as the microphone.

Upon installation of an audio reproduction system incorporating the present invention, the system itself, or a user, initiates a measurement sequence that automatically measures the decay time or reverberation time within the space or room using the installed audio reproduction system. The measured decay time or reverberation time is then used to calculate one or more correction filters that are then applied to the audio reproduction system. According to the invention, a single calculated correction filter can be used for all loudspeakers in the system, but it is also possible to apply different calculated filters to each individual loudspeaker or to groups of loudspeakers in the system. The measurement sequence can be initiated at any time should the user wish such as when the acoustical properties of the space or room are changed.

The then calibrated audio reproduction system should give the same intended listening experience regardless of the measured decay time or reverberation time within the listening space or room.

According to further aspects, the present invention also relates to an audio reproduction system comprising correction filter means receiving an audio signal and providing adjusted or corrected output signals to one or more loudspeakers, where said correction filter means has a filter curve C determined by the method according to the present invention or by the system according to the present invention.

The method and system according to the invention for adjusting or correcting timbre of an audio reproduction system can also be applied in connection with combinations of loudspeaker drivers, for instance mounted in a single cabinet, where all of said drivers or chosen drivers are provided with signals that are adjusted or corrected according to the invention. This is in the detailed description of the invention illustrated by combinations of a traditional loudspeaker driver and gradient loudspeakers.

### BRIEF DESCRIPTION OF THE FIGURES

The present invention will be more fully understood with reference to the following detailed description of embodiments of the invention in conjunction with the figures, where

FIG. 1 shows an enclosed space or room with a number of loudspeaker-microphone combinations and a number of loudspeakers without microphones placed throughout the space at any position;

FIG. 2 shows an example of a control set-up for the system, where a master unit controls the loudspeaker-microphone combinations and loudspeakers without microphones via a 2-way serial link;

FIG. 3 shows an example of a control set-up for the system, where one of the loudspeaker-microphone combinations is designated as the master unit and controls the other loudspeaker-microphone combinations and loudspeakers without microphones via a 2-way serial link;

FIG. 4 shows an example of a control set-up for the system, where a master unit controls the loudspeaker-microphone combinations and loudspeakers without microphones via 2-way parallel links;

FIG. 5 shows an example of a control set-up for the system, where one of the loudspeaker-microphone combinations is designated as the master unit and controls the other loudspeaker-microphone combinations and loudspeakers without microphones via 2-way parallel links;

FIG. 6 shows a block diagram of the measurement source, where a trigger from the master unit initiates a test signal that is reproduced by the loudspeaker in question and where the level of the test signal can be controlled;

FIG. 7 shows a block diagram of the measurement receiver, where a trigger from the master unit initiates the measuring sequence and where the microphone in question measures the impinging sound at its position, the microphone signal is amplified, the signal is then processed and final data is then available for this microphone position;

FIG. 8 shows that data from the microphone(s) in question can be combined, where this data is then weighted resulting in a new data set, which can be sent to the loudspeaker(s) in question and where some loudspeakers may have an interface that receives the data;

FIG. 9 shows a schematical representation of two different loudspeaker systems, i.e. a traditional system (to the left) with a loudspeaker unit or units typically mounted only on the front of an enclosure and a traditional loudspeaker provided with another electrically and acoustically separate combination of loudspeaker units mounted such that they face in another direction, a so-called gradient loudspeaker with, preferably, a bidirectional response;

FIG. 10 shows the audio signal path for correction of the timbre described by embodiment 1 with a traditional loudspeaker system and also the typical directivity of such a loudspeaker system;

FIG. 11 shows the audio signal path described by embodiment 2 with a traditional loudspeaker system in combination with a gradient loudspeaker system and also the typical directivity for these two loudspeaker systems;

FIG. 12 shows the audio signal path described by embodiment 3 with a traditional loudspeaker system in combination with a gradient loudspeaker system and also the typical directivity for these two loudspeaker systems;

FIG. 13 shows an average reverberation time curve Y (frequency in Hertz versus time in seconds) for a typical medium-sized listening space;

FIG. 14 shows a typical weighting function W;

FIG. 15 shows the reverberation time curve Y weighted with the function W to give a new weighted reverberation time curve C₁;

FIG. 16 shows the weighted reverberation time curve C₁ (solid curve) and the same curve forced to zero at the upper and lower ends of the frequency range C₂ (dashed curve);

FIG. 17 shows a smoothed version C₃ of the curve C₂;

FIG. 18 shows the smoothed curve C₃ (dashed curve) and the equalisation curve C₄ (solid curve) based upon the measured reverberation time Y shown in FIG. 13;

FIG. 19 shows the correction or equalisation curve C₄ shown as gain in decibels C₅;

FIG. 20 shows a reverberation time curve for an atypical listening space;

FIG. 21 shows the correction or equalisation curve in decibels for the reverberation time curve shown in FIG. 20;

FIG. 22 shows the weighted reverberation time curve C₁ (solid curve) and the same curve forced to the value at the Schroeder Frequency below that frequency C₂ (dashed curve) as described by embodiment 2;

FIG. 23 shows the smoothed version of C₂ curve C₃ (dashed curve) and the equalisation curve CGL1 (solid curve) based upon the measured reverberation time Y shown in FIG. 13 for embodiment 2;

FIG. 24 shows the correction or equalisation curve CGL1 shown as gain in decibels C₅;

FIG. 25 shows the correction or equalisation curve in decibels for the reverberation time curve shown in FIG. 20 for embodiment 2.

FIG. 26 shows the weighted reverberation time curve C₁ (solid curve) and the same curve forced to the value at the Schroeder Frequency below that frequency C₂ (dashed curve) as described by embodiment 3;

FIG. 27 shows the smoothed version of C₂ curve C₃ (dashed curve) and the equalisation curve CG21 (solid curve) based upon the measured reverberation time Y shown in FIG. 13 for embodiment 3;

FIG. 28 shows the correction or equalisation curve CGL2 shown as gain in decibels C₅; and

FIG. 29 shows the correction or equalisation curve in decibels for the reverberation time curve shown in FIG. 20 for embodiment 3.

### DETAILED DESCRIPTION OF EMBODIMENT 1 OF THE INVENTION

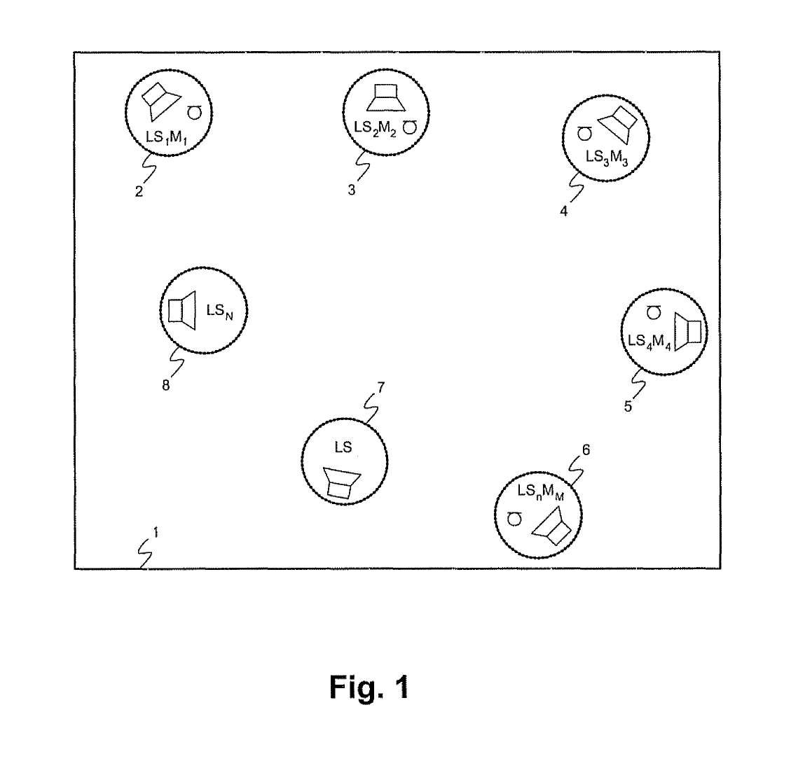

Referring to FIG. 1, a number of loudspeaker-microphone combinations 2, 3, 4, 5 and 6 are installed in a listening space or room 1. They are connected together with a 2-way network (not shown in the figures) and one of the loudspeaker-microphone combinations, or a separate part of the sound reproduction system such as an audio unit (CD/radio player or Hard Disc system or server), is designated as the master unit. The number of loudspeaker-microphone combinations can be supplemented with a number of loudspeakers 7 and 8 without microphones, potentially via an interface(s).

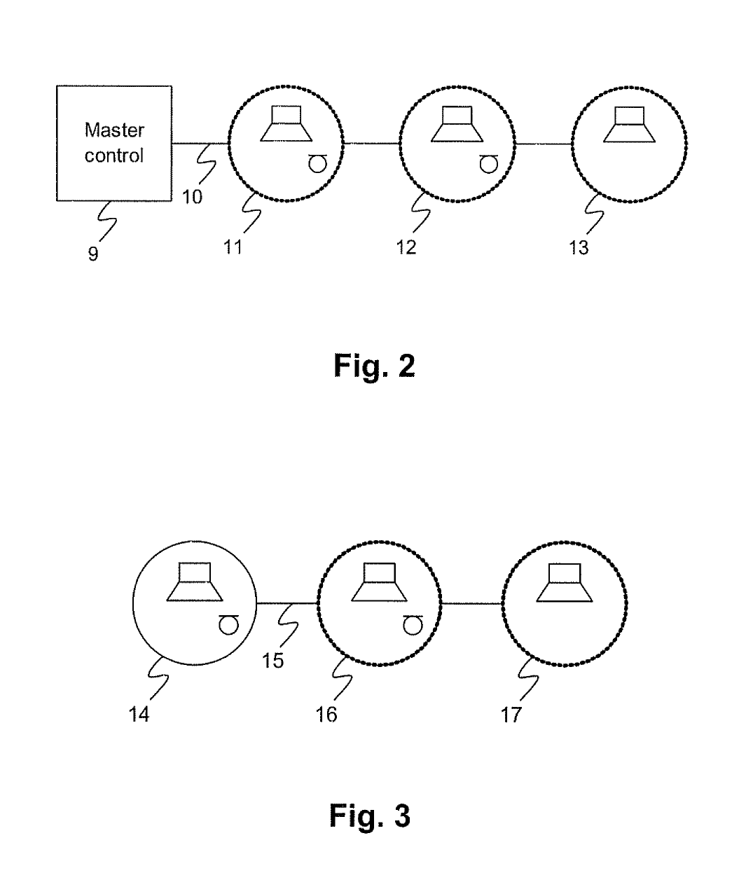

With reference to FIGS. 2 through 5, various loudspeaker/microphone/control unit combinations are illustrated, but other configurations would also fall within the scope of the present invention. Thus, FIG. 2 shows an example of a control set-up for a system according to the invention, where a master unit 9 controls the loudspeaker-microphone combinations 11, 12 and loudspeakers 13 without microphones via a 2-way serial link.

FIG. 3 shows an example of a control set-up for the system, where one of the loudspeaker-microphone combinations 16 is designated as the master unit and controls the other loudspeaker-microphone combinations and loudspeakers without microphones via a 2-way serial link.

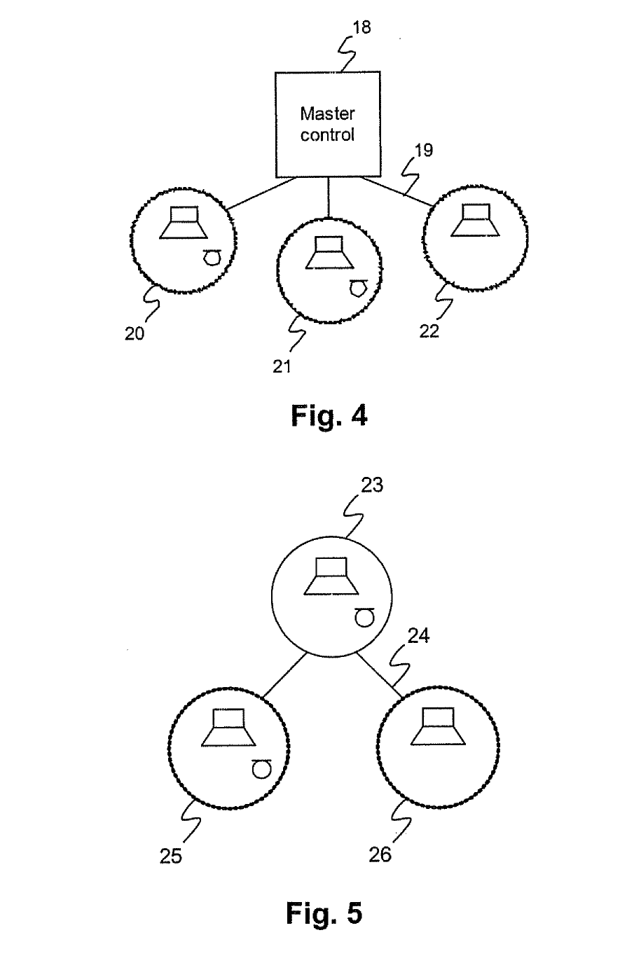

FIG. 4 shows an example of a control set-up for the system, where a separate master unit 18 controls the loudspeaker-microphone combinations and loudspeakers without microphones via 2-way parallel links.

FIG. 5 shows an example of a control set-up for the system, where one of the loudspeaker-microphone combinations 25 is designated as the master unit and controls the other loudspeaker-microphone combinations and loudspeakers without microphones via 2-way parallel links.

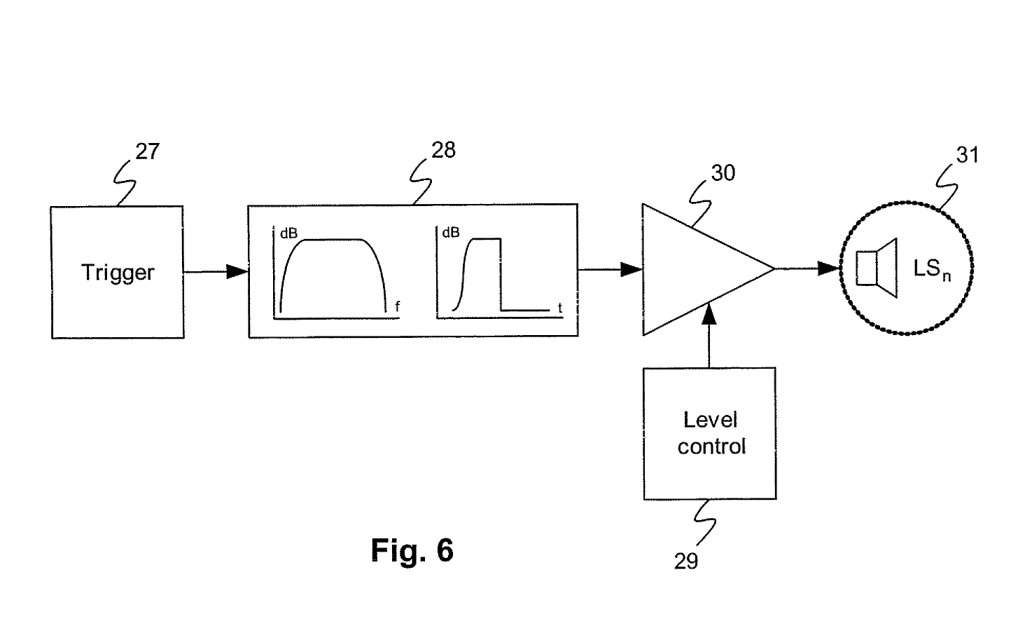

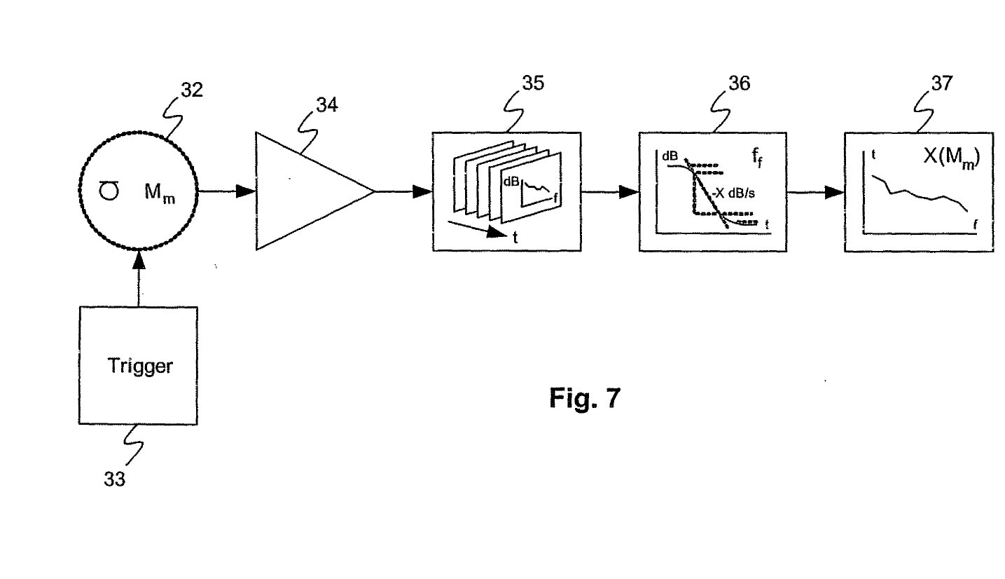

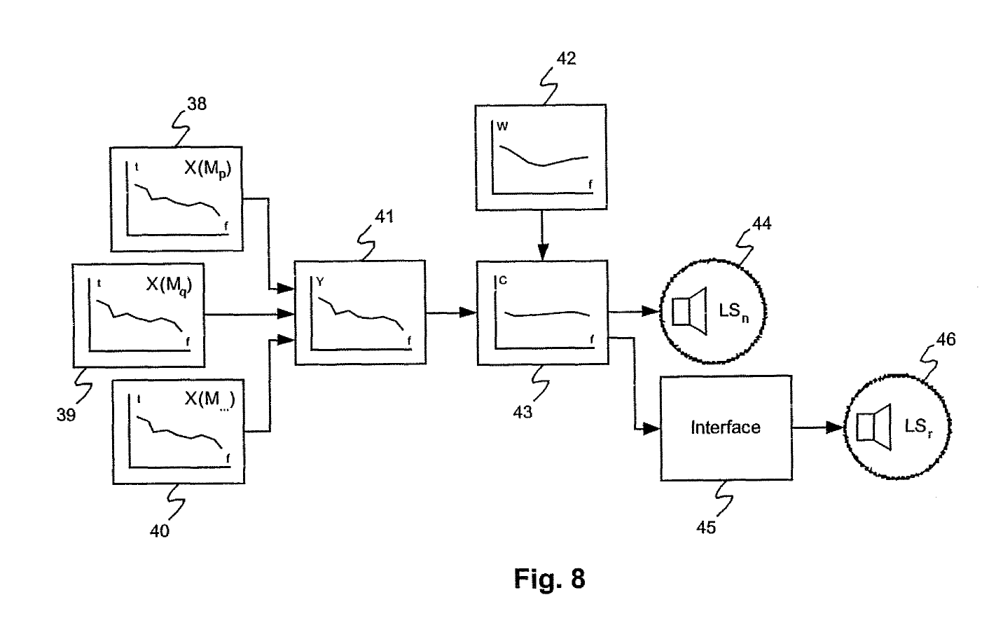

Once the system according to the invention is connected, the measurement process can be initiated as schematically illustrated in FIGS. 6-7. Referring to FIG. 6, the designated master unit triggers 27 the first loudspeaker LS₁ (reference numeral 2 in FIG. 1 and reference numeral 31 in FIG. 6) to reproduce the test signal 28. The test signal is a band-limited signal that can excite the sound field in the listening space or room 1. The level of the test signal is controlled as schematically indicated by the amplifier 30, the gain of which can be controlled as indicated by the level control 29, such that a sufficient sound pressure level is obtained within the listening space or room and at the measuring microphones in the audio reproduction system when the test signal is active. The test signal is preferably an interrupted signal. When the test signal is reproduced by loudspeaker LS₁ (2 or 31), the measurement receivers in the system (see FIG. 7), i.e. the microphones (32 in FIG. 8) and associated signal processing means 34, 35, 36, 37, are triggered 33 to measure the impinging sound at the microphones. It is the decay of sound within the listening space or room when the test signal is interrupted that is relevant for the measurement of decay time or reverberation time. The relevant period of time can be divided into three intervals:
a) a period where the test signal is at its maximum or steady-state level,
b) a period of decay immediately after the test signal is interrupted,
c) a period of background noise.

The individual microphone signals are amplified by suitable amplifier means 34 and subsequently processed as indicated by reference numerals 35 and 36. At least two methods could be used:
1) The processing can involve Fast Fourier Transforms (FFTs) of the microphone signal at a certain frequency resolution and at discrete time intervals for a period of time as schematically indicated by block 35 in FIG. 7. The FFT information is grouped into frequency bands f_{f} and a slice of data for each frequency band is calculated for the period of time in question as indicated by reference numeral 36.
2) Alternatively, the microphone signal can be filtered with filter banks (digital or analogue) into the desired frequency bands f_{f} and a slice of data for each frequency band is calculated for the period of time in question 36.

Within each frequency band f_{f} the level of time intervals (a) and (c) is calculated and a suitable interval for the measurement of the sound decay is selected. The steady state level (a) is determined from an average of the initial levels within the measurement slice. The end of this steady state period (the start of the decay) is determined when the average level of a number of following points in the slice falls below the first average level less a limit value. The level of the background noise (c) is determined in a similar manner by calculating an average level at the end of the measurement slice and by finding the end of the decay (when the average level of a preceding number of points rises above the calculated average by a limit value). The rate of decay −X dB/s is then determined by linear regression from the data points within the period of decay (b) within each frequency band f_{f}. The result is a data set X(Mₘ) for each microphone position Mₘ which is a function of frequency. The data set X(Mₘ), reference numeral 37, consists of decay time versus frequency band.

The measurement process described is repeated for each loudspeaker LSₙ such that each loudspeaker in turn reproduces the test signal to be measured by the microphones in the audio reproduction system.

All the data sets are collected by the designated master unit and are processed as schematically illustrated by the block diagram in FIG. 8. The number of individual data sets will usually be M(N−1), where N is the total number of loudspeakers in the audio reproduction system and M is the total number of microphones in the audio reproduction system. This indicates that according to a specific embodiment of the invention, the microphone in a loudspeaker-microphone combination is not included in the measurement when the loudspeaker in the said combination reproduces the test signal. However, the invention also relates to the specific case, where the calculations may comprise the microphone signal from the loudspeaker-microphone combination actually emitting the sound.

The data sets X(Mₘ) can now be used to calculate a correction or corrections for the audio reproduction system. In the simplest case, all of the data sets can be combined (reference numeral 41) using a simple average of the individual data sets X(M_{M}) for each frequency f_{f}, as follows:

$$Y = \frac{\sum X ( {M}_{m} )}{M ( N - 1 )}$$

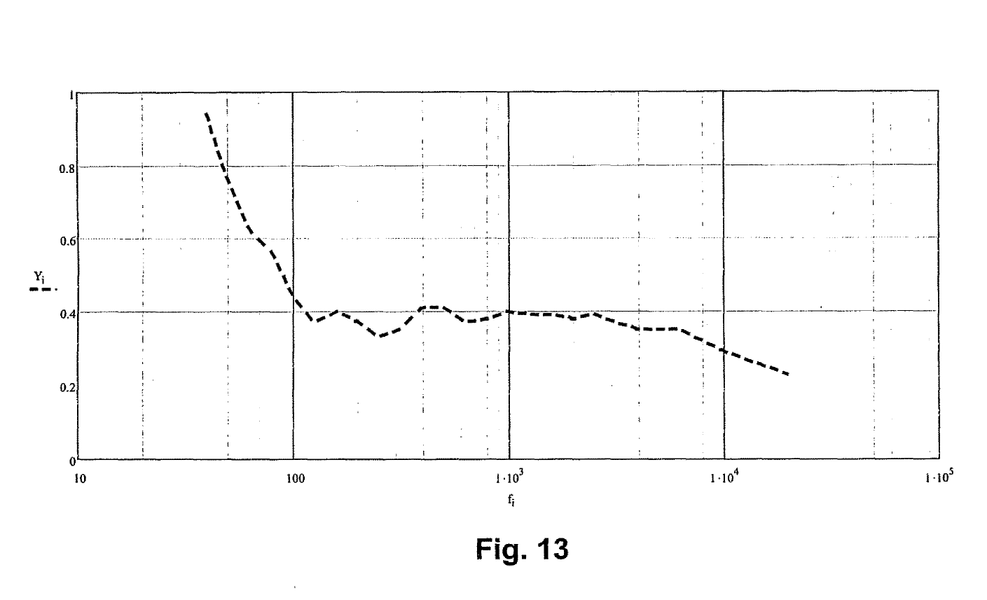

The resulting combined data set Y is a function of frequency. A typical data set is shown in FIG. 13 that illustrates an average reverberation time curve Y (frequency in Hertz versus time in seconds) for a typical medium-sized listening space.

As previously mentioned, the present invention is according to a specific embodiment also applicable in cases, where the test signal is emitted from a given loudspeaker and the resulting sound decay, after interruption of the test signal, is recorded by means of a microphone provided in the same loudspeaker as the loudspeaker emitting the test signal. Instead of using a microphone, the loudspeaker itself may even be used to record the sound decay by using the loudspeaker as a microphone. In this case the above expression should be replaced by:

$$Y = \frac{\sum X ( {M}_{m} )}{MN}$$

Furthermore, in the case where only a single loudspeaker/microphone is present in the system, this expression reduces to:

Y=X(Mₘ)

In a more complicated case, the individual data sets can be combined as described above, but in groups that have similar data, or combined in areas within the listening space or room, should the listening space have significantly differing acoustic properties from one area within the space to another area within the space, for example if there are ‘live’ and ‘dead’ areas of the listening space or room.

Data points within a data set that differ significantly from the average value can be automatically excluded from the calculation of the final combined data set Y.

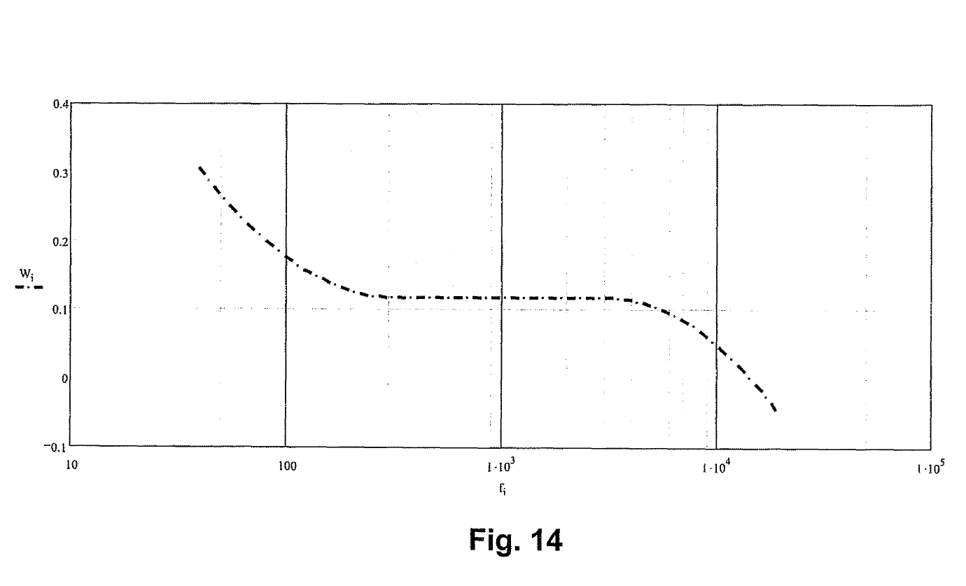

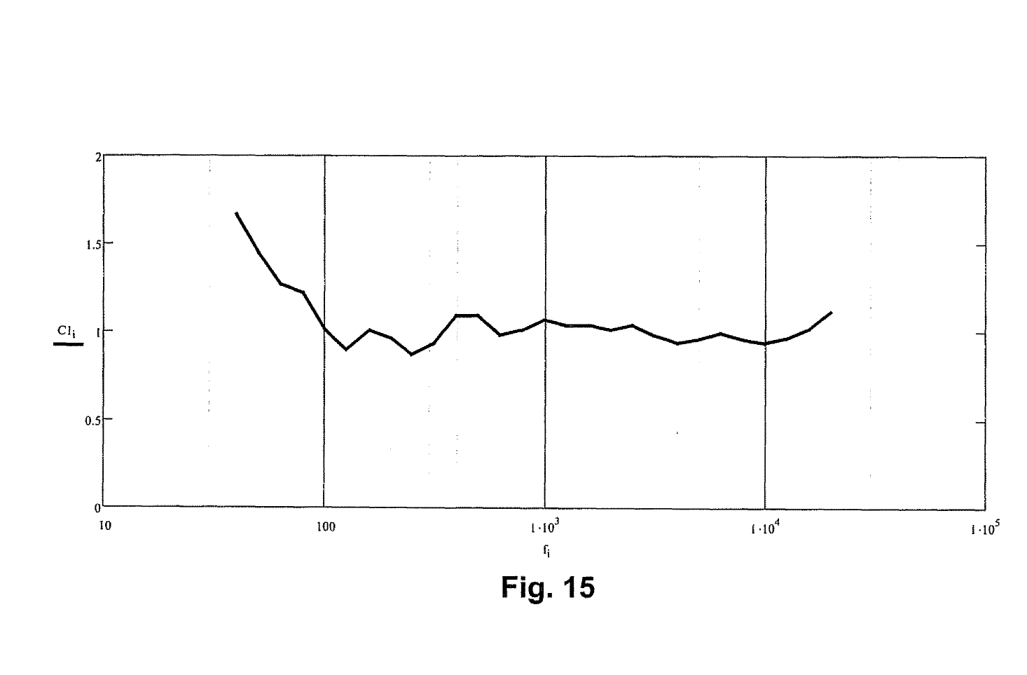

The combined data set or sets can be transposed with a weighting curve or curves 42 (see also FIG. 14) into a correction curve or curves 43 (see also FIG. 15) that can be applied to some or all of the loudspeakers in the audio reproduction system 44. For loudspeakers that do not have network or internal digital signal processor capabilities, the correction can be applied by an interface 45 or by the master unit.

The weighting curve W (FIG. 14) typically describes, but is not limited to, the decay time in a reference listening space or room, where the values have been shifted such that the weighting curve has a nominal value of zero between two predefined frequencies. In the example of the curve described in FIG. 14, the two frequencies are 10 kHz and 20 kHz.

The data set Y (FIG. 13) is at least according to the shown embodiment weighted by the function W (FIG. 14) which itself is offset by a factor O, where O is typically the average value of the curve Y between two frequencies as follows:

$${C}_{1} = \frac{Y}{W + O}$$

The resulting weighted curve is shown in FIG. 15, where O is the average value of the data Y between two predefined frequencies. In the example of the curve described in FIG. 15, the two frequencies are 10 kHz and 20 kHz.

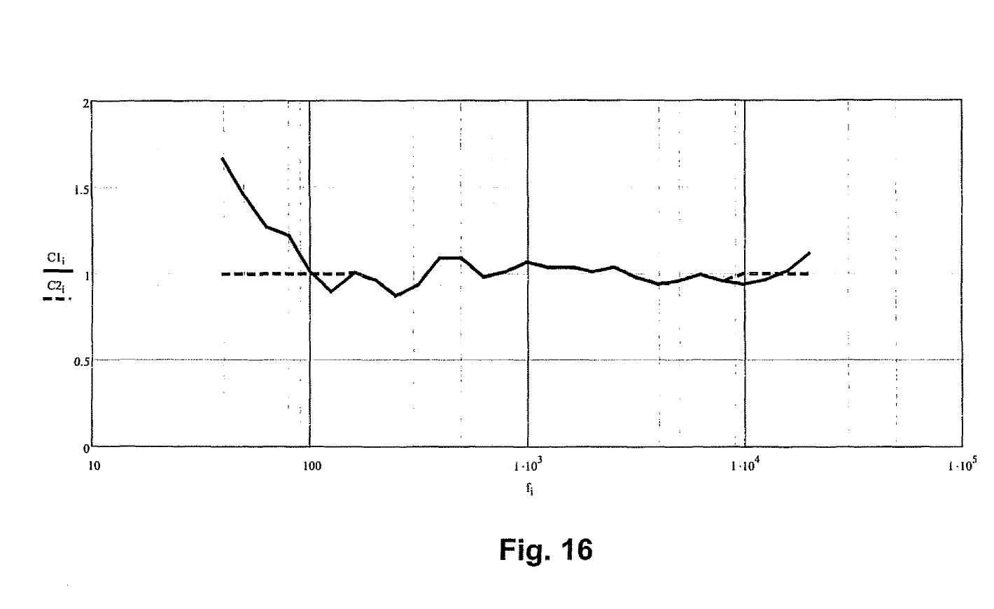

The resulting data C₁ is then typically forced to unity at low and high frequencies as shown in FIG. 16. The low frequencies where the data is forced to unity are typically below the Schroeder Frequency for the listening space or room.

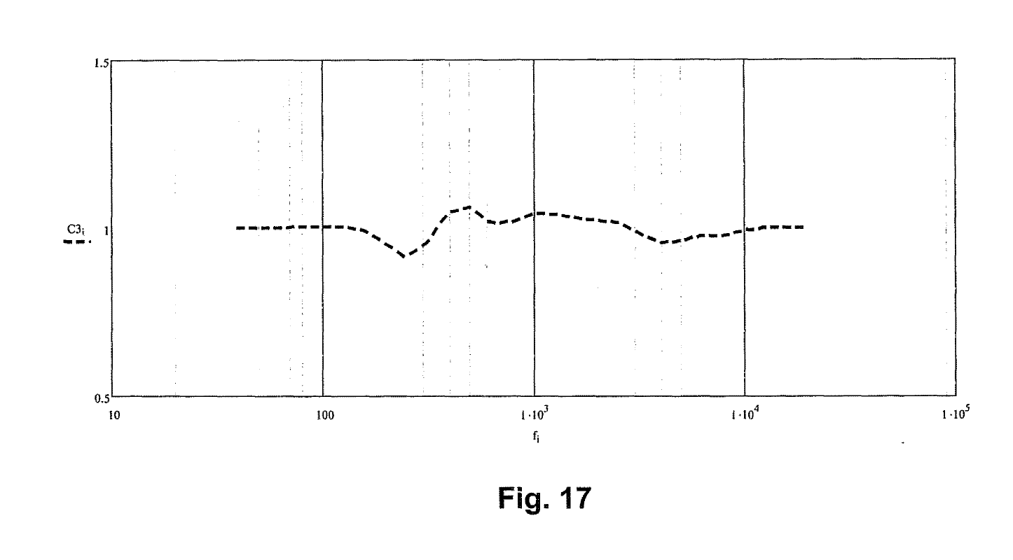

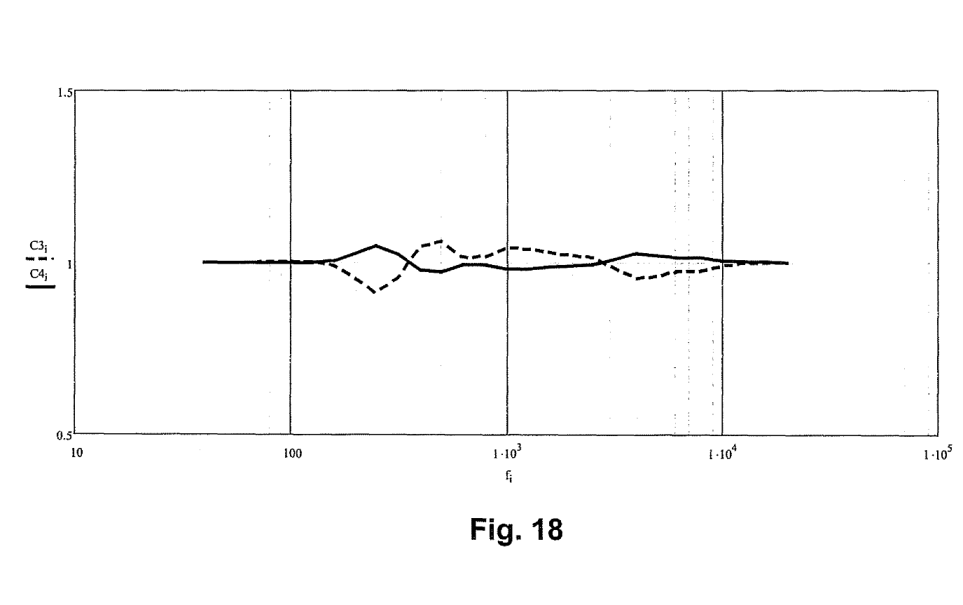

The new data C₂ (see FIG. 16) is then typically smoothed with a simple smoothing function to give a new curve C₃ as shown in FIG. 17. The equalisation curve C₄ as shown in FIG. 18 is derived from the data set C₃ as follows:

$${C}_{4} = G ( \frac{1}{{C}_{3}} )$$

The function G can be, but is not limited to, a simple square-root function such that for a doubling of the decay time a correction of √0.5 or 0.707 is made, however the function G is typically more non-linear in a fashion that compresses high gains if a limit is desired due to system limitations such as headroom.

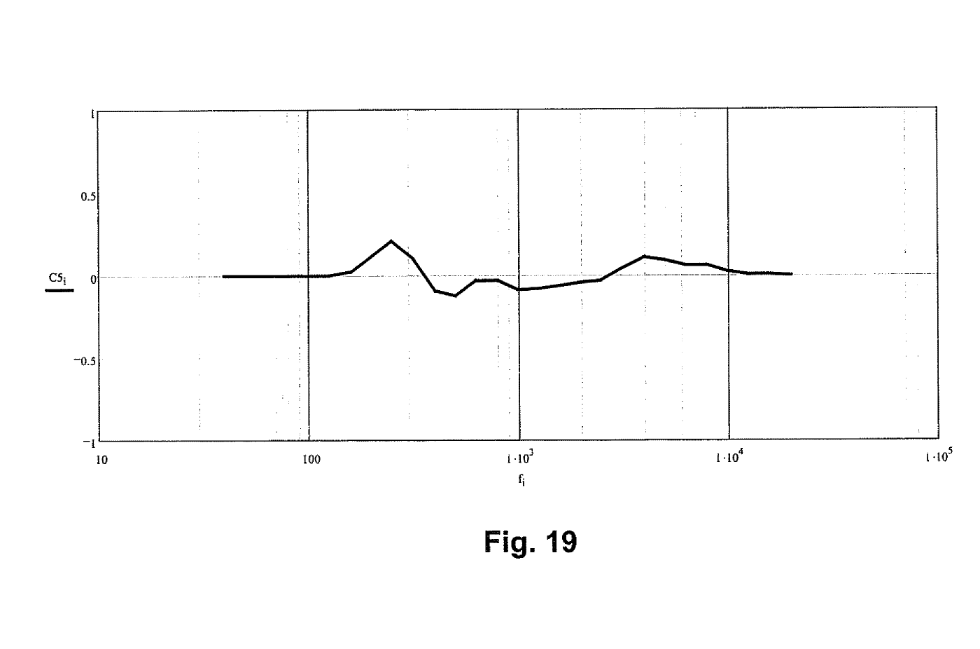

This correction or equalisation curve (FIG. 18), which is a function of gain versus frequency, can now be applied to the sound reproduction system. FIG. 19 shows the correction or equalisation curve C₄ in decibels.

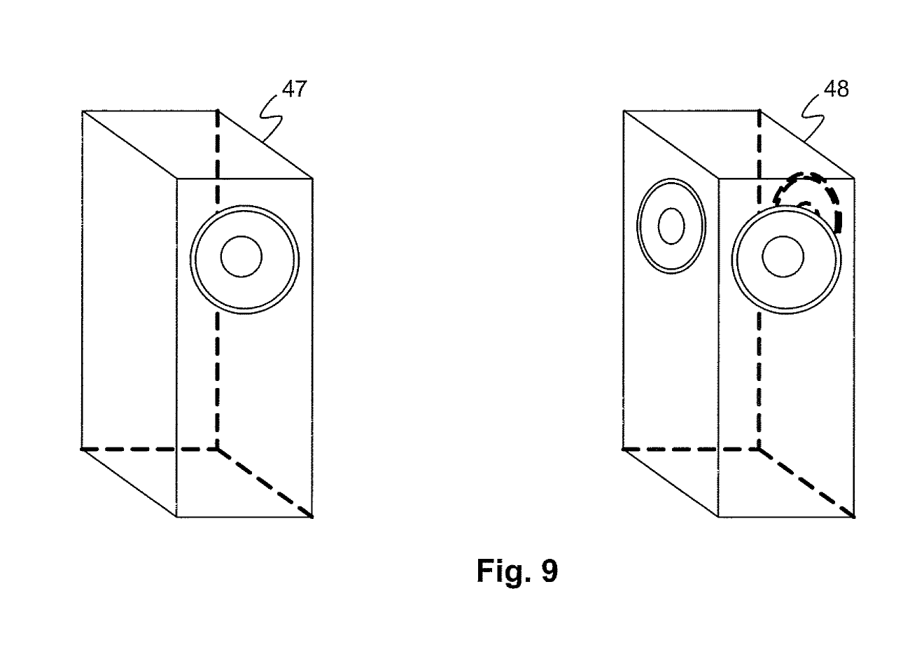

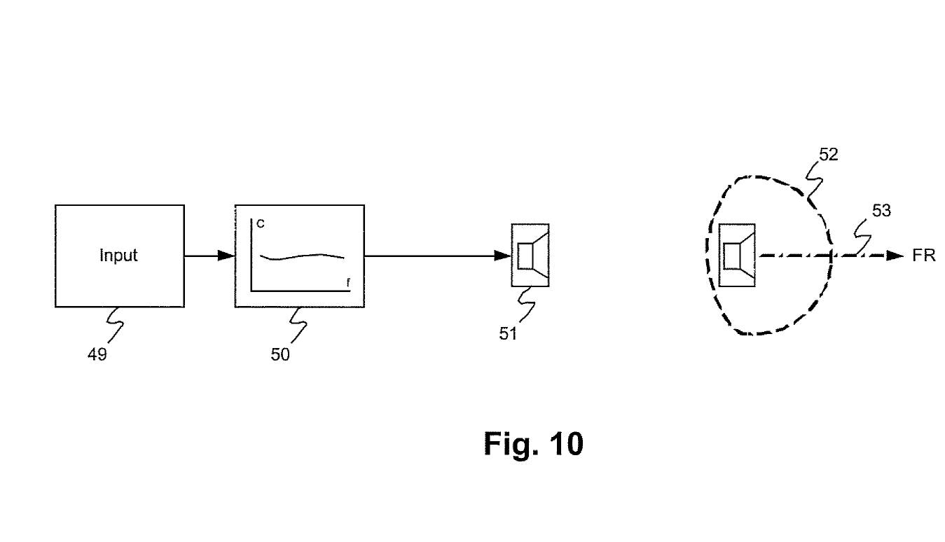

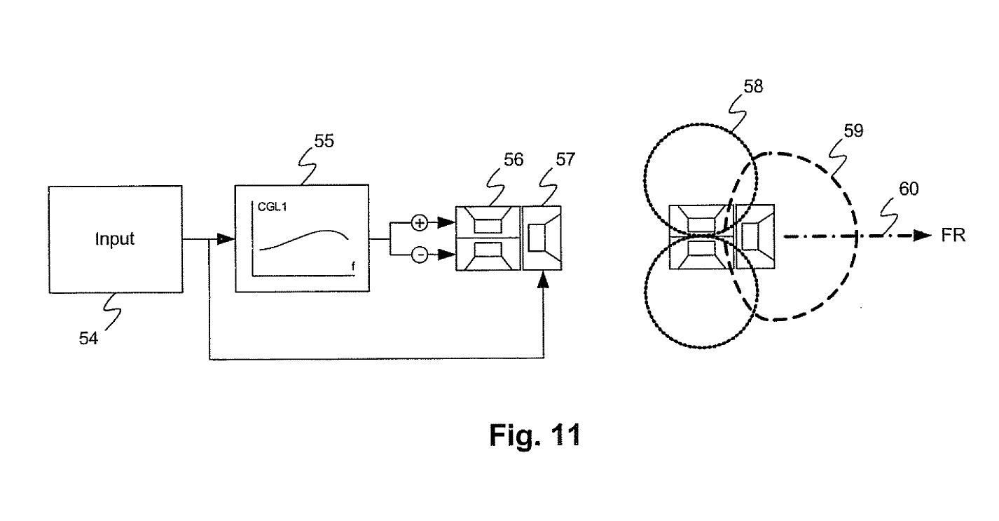

In this embodiment of the invention, this correction filter or equalisation curve C₄ is applied to the audio signal path as shown in FIG. 10 for a traditional loudspeaker system 51 which is shown schematically in FIG. 9 designated by reference numeral 47. This loudspeaker system is preferably a multi-way active design, but may be full-range and/or passive. Changes to the signal from the signal source 49 by the correction filter 50 will directly affect the loudspeaker system's frequency response 53 and power response, thus changing the response within the listening space or room according to the measured decay time Y. 52 represents a typical directivity pattern for a traditional loudspeaker system.

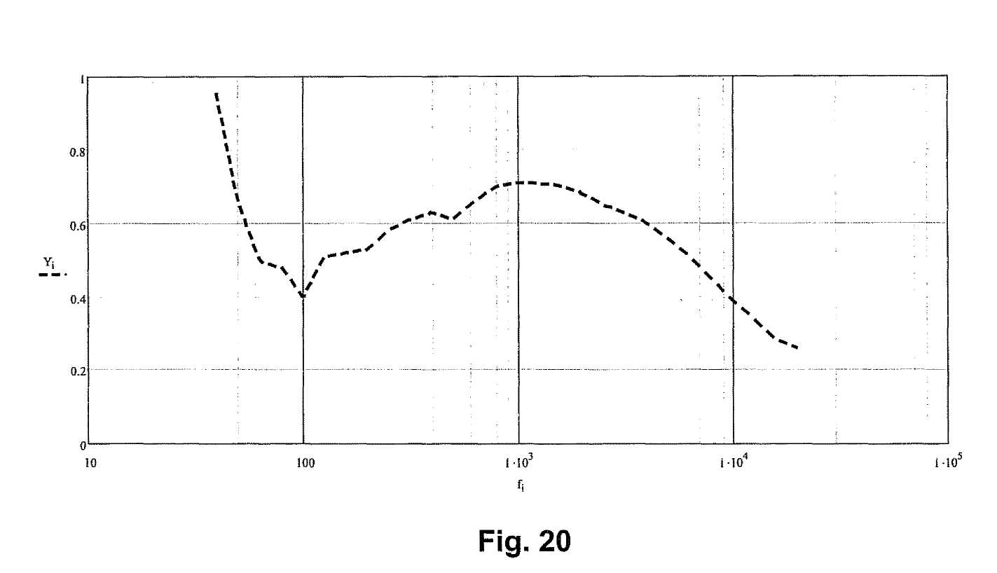

FIG. 20 shows an atypical reverberation time curve (higher values of reverberation time at mid frequencies (around 1 kHz) than in the upper bass region around 100 Hz) for another listening space or room.

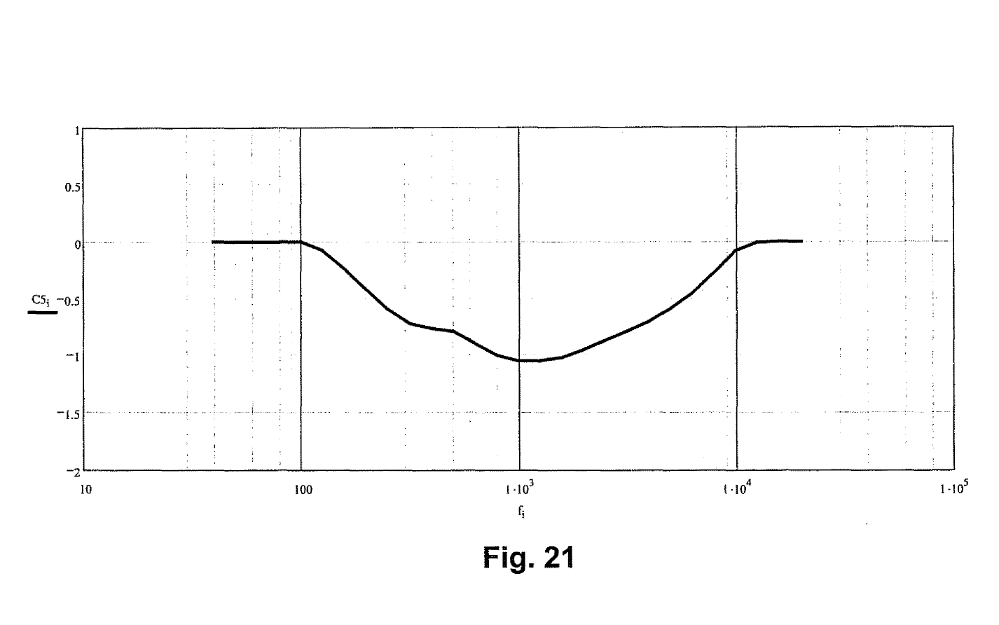

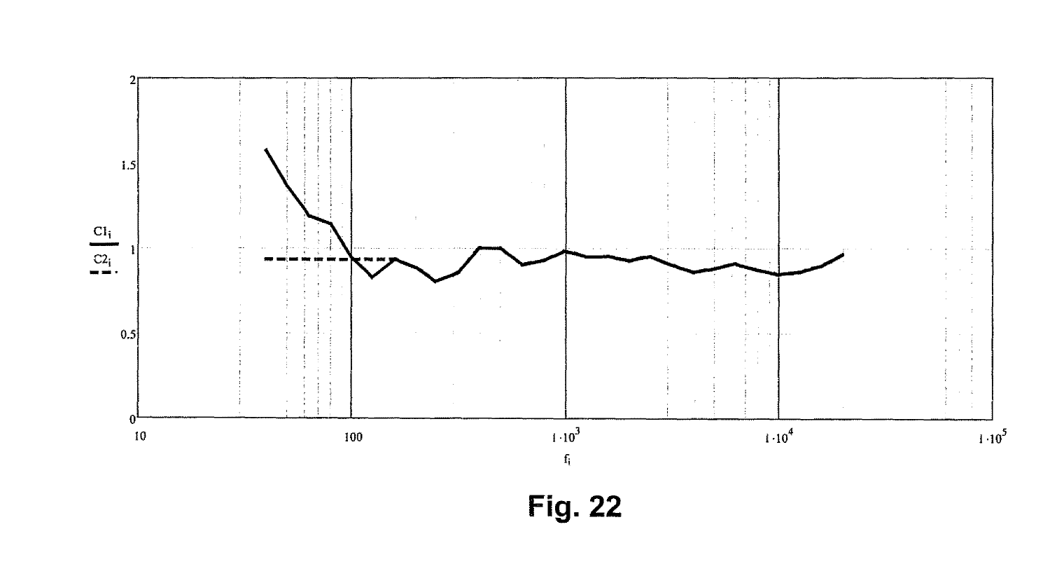

FIG. 21 shows a correction or equalisation curve in decibels for this space.

Once applied, the correction remains as an active part of the audio reproduction system until it is disabled or until the system is re-calibrated, for example, if the system is moved to another listening space or room, or more loudspeaker-microphone combinations or loudspeakers are added to the system, or the acoustic properties of the listening space or room are changed.

### DESCRIPTION OF EMBODIMENT 2 OF THE INVENTION

Reverting to FIG. 9, there is shown a simple representation of two different loudspeaker systems. 47 represents a traditional system with a loudspeaker unit or units typically mounted only on the front of an enclosure. 48 represents a traditional loudspeaker with a unit or units typically mounted only on the front of an enclosure and another electrically and acoustically separate combination of loudspeaker units mounted such that they face in another direction, a so-called gradient loudspeaker with, preferably, a bidirectional response.

According to the second embodiment of the invention, the correction filter or equalisation curve 55 is applied as shown in FIG. 11 for a traditional loudspeaker system 57 combined with a gradient loudspeaker system 56 which is shown schematically in FIG. 9. The system is designated by reference numeral 48 and represents a traditional loudspeaker with a unit or units typically mounted on the front of an enclosure and another electrically and acoustically separate combination of loudspeaker units mounted such that they face in another direction, Referring to FIG. 11, this additional combination of drive units is designed and driven in such a way to achieve a certain directivity response 58 with a null on the axis 60 of the traditional forward-facing drive unit or units by means of a so-called gradient loudspeaker 56 with, preferably, a bidirectional response. 59 represents a typical directivity pattern for the traditional loudspeaker system, i.e. for the loudspeaker system 57 itself. Each of these two loudspeaker systems is preferably a multi-way active design but may be full-range and/or passive. The signal from a signal source 54 is fed through the correction filter 55 and thereafter to the gradient loudspeaker system 56. The original signal is also fed to the traditional loudspeaker system 57. Therefore, the correction filter will affect the loudspeaker system's power response, thereby correcting the non-direct sound field in a space or room according to the measured decay time Y. According to embodiment 2 as shown schematically in FIG. 11, it is only possible to increase the power radiated from the loudspeaker system according to the measured decay time Y. The data set Y (FIG. 13) is at least according to the shown embodiment weighted by the function W (FIG. 14) which itself is typically aligned W₁ to coincide with the measured decay time Y at the frequency with the greatest measured decay time within the frequency range of interest, typically above the Schroeder Frequency as follows:

$${C}_{1} = \frac{Y}{{W}_{1}}$$

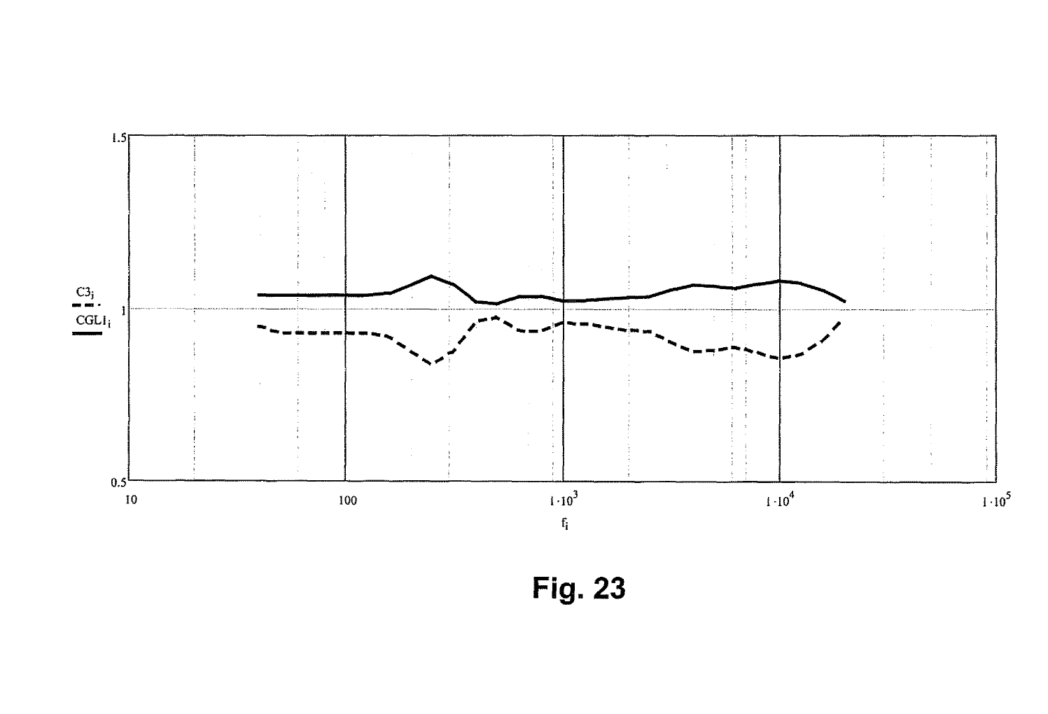

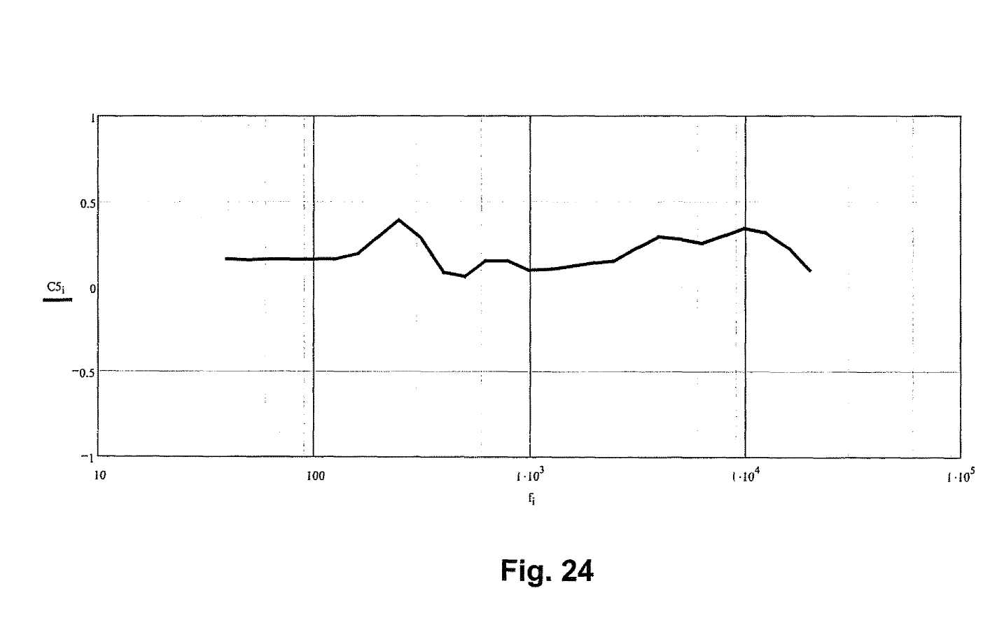

The resulting data lying below the Schroeder Frequency is typically forced to the value at the Schroeder Frequency as shown in FIG. 22. The new data C₂ is then typically smoothed with a simple smoothing function to give a new function C₃ as shown in FIG. 23. The equalisation curve CGL1 as also shown in FIG. 23 is derived from the data set C₃ as follows:

$$CGL 1 = H ( \frac{1}{{C}_{3}} )$$

The function H can be, but is not limited to, a simple square-root function such that for a doubling of the decay time a correction of √0.5 or 0.707 is made, however the function H is typically more non-linear in a fashion that compresses high gains if a limit is desired due to system limitations such as headroom.

This correction or equalisation curve (FIG. 23), which is a function of gain versus frequency, can now be applied to the sound reproduction system as shown schematically in FIG. 11. FIG. 24 shows the correction or equalisation curve CGL1 in decibels.

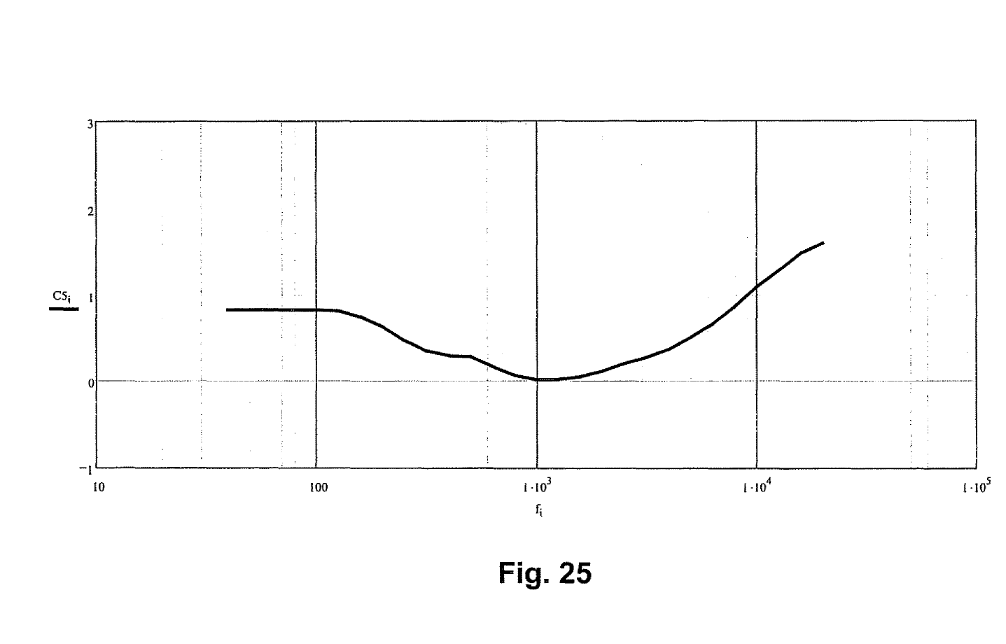

FIG. 25 shows a correction or equalisation curve in decibels according to embodiment 2 for the decay time curve shown in FIG. 20.

Once applied, the correction remains as an active part of the audio reproduction system until it is disabled, or until the system is re-calibrated, for example, if the system is moved to another listening space or room, or more loudspeaker-microphone combinations or loudspeakers are added to the system, or the acoustic properties of the listening space or room are changed.

### DESCRIPTION OF EMBODIMENT 3 OF THE INVENTION

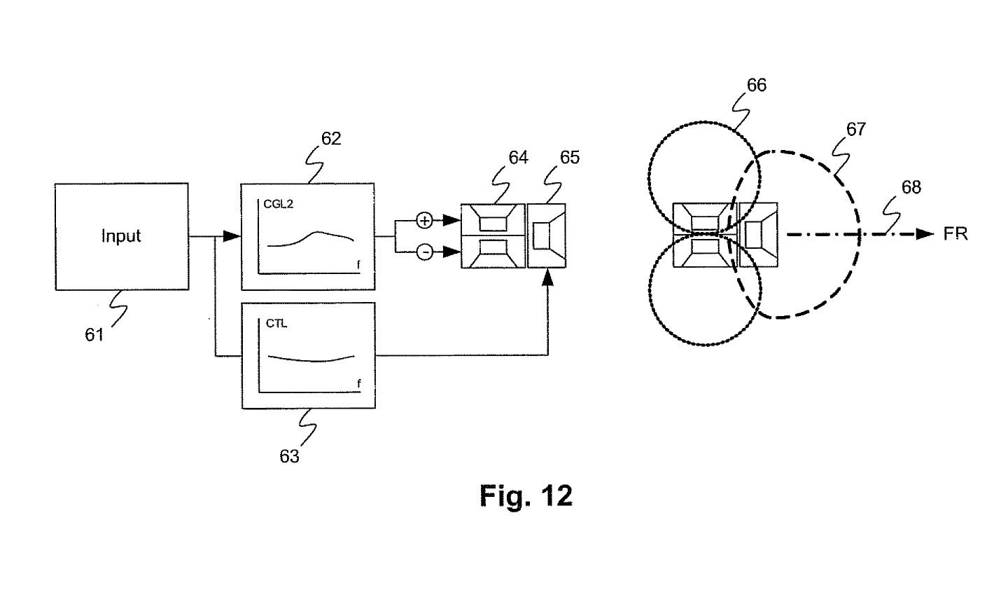

In this embodiment of the invention, the correction filter or filters or equalisation curve or curves 62 and 63 are applied as shown in FIG. 12 for a traditional loudspeaker system 65 combined with a gradient loudspeaker system 64 which is shown schematically in FIG. 9. This loudspeaker system is designated by reference numeral 48 in FIG. 9 and represents a traditional loudspeaker with a unit or units typically mounted on the front of an enclosure and another electrically and acoustically separate combination of loudspeaker units mounted such that they face in another direction. This additional combination of drive units are designed and driven in such a way to achieve a certain directivity response 66 with a null on the axis 68 of the traditional forward-facing drive unit or units, a so-called gradient loudspeaker with, preferably, a bidirectional response. The gradient loudspeaker in itself is a known acoustical method. 67 represents a typical directivity pattern for the traditional loudspeaker system 65. Each of these two loudspeaker systems is preferably a multi-way active design but may be full-range and/or passive. The signal from a signal source 61 is fed through the correction filters 62 and 63 and thereafter to a gradient loudspeaker system 64 and a traditional loudspeaker system 65, respectively. Therefore, the correction filter will affect the loudspeaker system's power response, thereby correcting the non-direct sound field in a space or room according to the measured decay time Y. According to embodiment 3 as shown schematically in FIG. 12, it is possible both to increase the power radiated from the loudspeaker system and reduce the power radiated from the loudspeaker system according to the measured decay time Y. The data set Y (FIG. 13) is at least according to the shown embodiment weighted by the function W (FIG. 14) which itself is typically aligned W₂ to the measured decay time Y such that the corrected response of the loudspeaker system can maintain the same loudness level for a given input as follows:

$${C}_{1} = \frac{Y}{{W}_{2}}$$

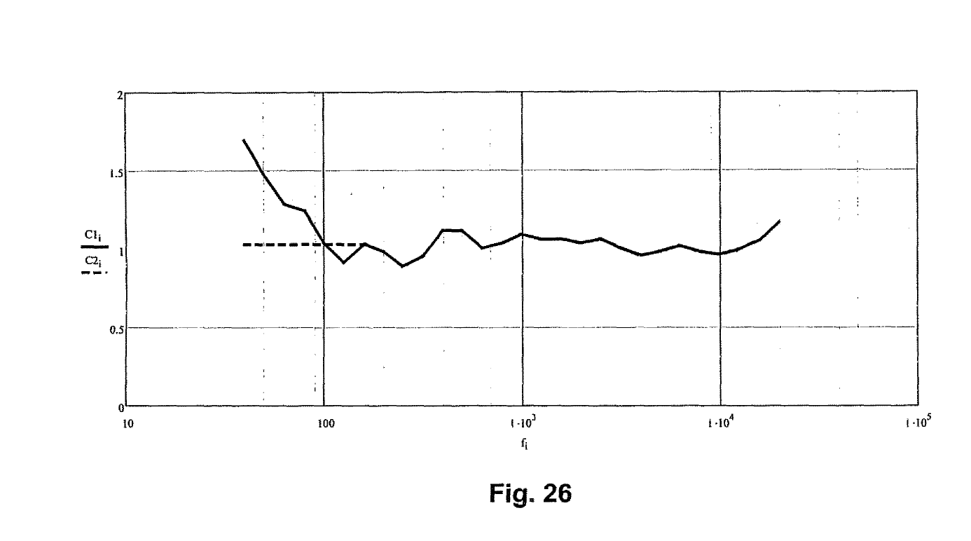

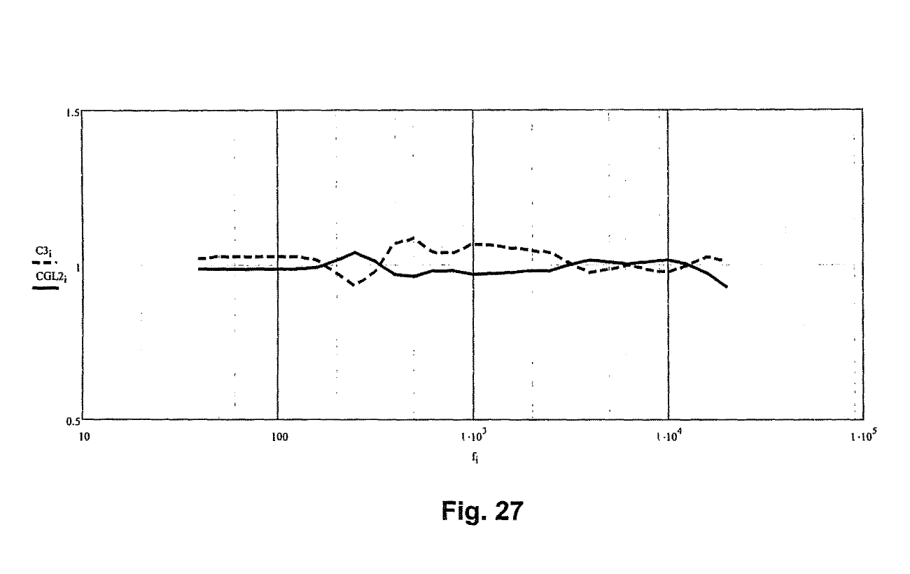

The resulting data lying below the Schroeder Frequency is typically forced to the value at the Schroeder Frequency as shown in FIG. 26. The new data C₂ is then typically smoothed with a simple smoothing function to give a new function C₃ as shown in FIG. 27. The equalisation curve CGL2 as also shown in FIG. 27 is derived from the data set C₃ as follows:

$$CGL 2 = I ( \frac{1}{{C}_{3}} )$$

The function I can be, but is not limited to, a simple square-root function such that for a doubling of the decay time a correction of √0.5 or 0.707 is made, however the function I is typically more non-linear in a fashion that compresses high gains if a limit is desired due to system limitations such as headroom.

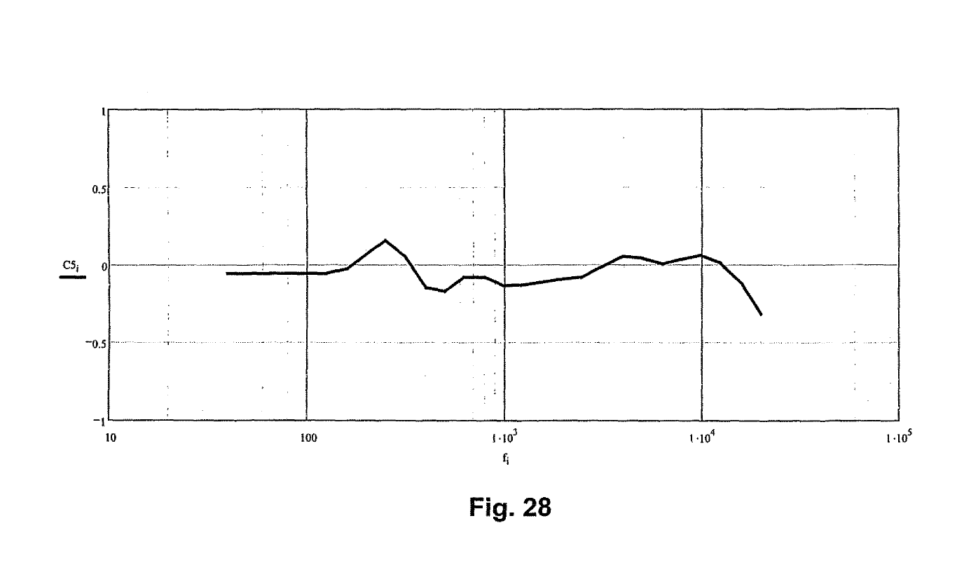

This correction or equalisation curve (FIG. 27), which is a function of gain versus frequency, can now be applied to the sound reproduction system as shown schematically in FIG. 12. FIG. 28 shows the correction or equalisation curve CGL2 in decibels.

The correction curve CTL as shown schematically in FIG. 12 can be, but is not limited to, a simple gain function to reduce the output level of loudspeaker reference numeral 65 in order to reduce the power output from the loudspeaker system but maintain the on axis response reference numeral 68 of the system.

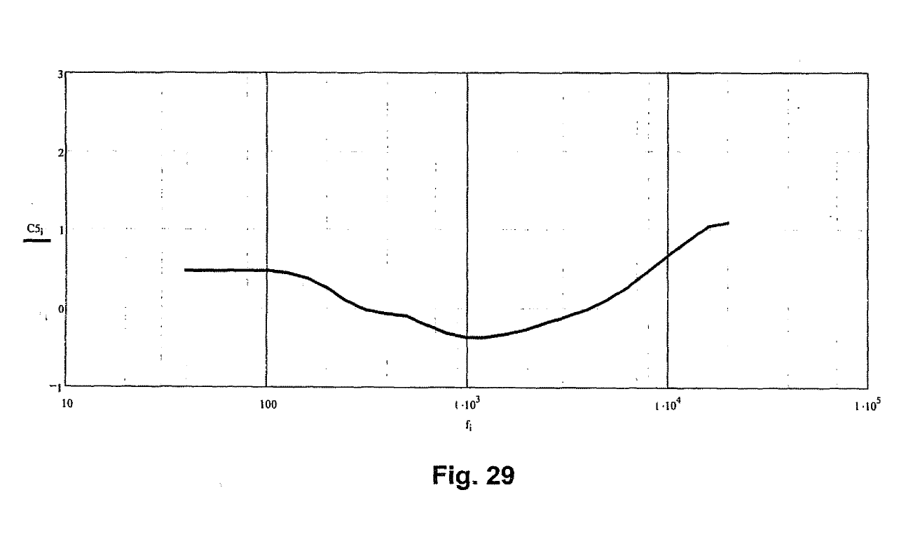

FIG. 29 shows a correction or equalisation curve in decibels according to embodiment 3 for the decay time curve shown in FIG. 20.

Once applied, the correction remains as an active part of the audio reproduction system until it is disabled or until the system is re-calibrated, for example, if the system is moved to another listening space or room, or more loudspeaker-microphone combinations or loudspeakers are added to the system, or the acoustic properties of the listening space or room are changed.

1. The use of a pre-determined function describing the decay of acoustical energy in a room, such as the decay time or reverberation time RT of a room or other at least partially enclosed space as a function of frequency for adjusting or correcting directly the timbre of sound reproduced by a sound reproduction system in said room or other at least partially enclosed space.

2. A method for adjusting or correcting directly the timbre of sound reproduced by at least one transducer, such as a loudspeaker in a room or other at least partially enclosed space, the method comprising
determining a function describing the decay of acoustical energy such as the decay time or reverberation time RT of said room or space as a function of frequency;
based on said function, such as the said decay time or said reverberation time RT, determining a correction curve (filter characteristic) C as a function of frequency, where said correction curve C is a function of said function, such as the decay time or reverberation time RT;
implementing said correction curve (filter characteristic) as an electronic filter;
processing an electrical signal via said electronic filter and providing the processed signal to one or more of said transducers and/or additional transducers.

3. A method according to claim 2, characterised in that said determining of the decay time or reverberation time RT is obtained by using at least one sound source, such as a loudspeaker and at least one sound sensitive means, such as a microphone, where the at least one sound source emits a test signal and said at least one sound sensitive means picks up the sound generated in said room or other space by said test signal and where said decay time or reverberation RT as a function of frequency is calculated based on the sound picked up by the sound sensitive means.

4. A method according to claim 2, characterised in that said correction curve C is substantially equal to a scaled version of the inverse function of RT or decay time over a given frequency range.

5. A method according to claim 2, where said decay time or reverberation time RT is processed by a weighting function W prior to being used for determining said correction curve C.

6. A method according to claim 2, characterised in that a given one of said sound sources and a given one of said sound sensitive means are incorporated in a separate unit, whereby the unit can both emit sound to said room and measure a sound field in said room.

7. A method according to claim 2, characterised in that said sound source and said sound sensitive means are implemented as a single unit provided with means that can both function to emit sound energy when driven by electrical energy and convert sound energy to electrical energy, when acted upon by a sound field.

8. A method according to any preceding claims, where said decay time or reverberation time RT is determined as an average Y of individual decay times or reverberation times X(Mm) determined for a number of different loudspeaker/microphone combinations in said room of space, where said number can specifically by equal to one, corresponding to a single loudspeaker/microphone combination.

9. A method according to any of the preceding claims, where said correction curve C is calculated by the following expressions:
$${C}_{1} = \frac{Y}{W + O}$$
where W is a weighting function and O is the average value of Y in a predefined frequency range; and where said correction curve C is a function of G of 1/C₁ or a function G of 1/F(C₁), where F represents a processing carried out on C1, such as smoothing of C₁.

10. A method according to claim 9, where said function G is a square root function.

11. A system for adjusting or correcting the timbre of an audio signal reproduced by at least one loudspeaker in a room, the system comprising:
at least one sound source, such as a loudspeaker for emitting sound energy to said room, thereby creating a sound field in said room;
at least one sound sensitive means, such as a microphone for converting acoustical energy from said sound field in the room to electrical energy;
means for generating a test signal for emission by said at least one sound source into said room;
means for determining a function describing the decay of acoustical energy such as the decay time or the reverberation time RT as a function of frequency based on said test signal and on a signal provided by said at least one sound sensitive means;
means for determining a correction curve (filter characteristic) C as a function of frequency, where said correction curve C is a function of said function, such as the decay time or reverberation time RT;
correction filter means, the frequency response of which is determined based on said correction curve C;
whereby said correction filter means can be used for processing an electrical signal and where the processed electrical signal is provided to one or more of said sound sources.

12. A system according to claim 11, where said test signal is an interrupted signal.

13. A system according to claim 11 or 12, where the system comprises means for, based on an output signal from a given microphone (Mm), calculating the specific decay time or reverberation time X(Mm) for that microphone (Mm) as a function of frequency and optionally storing said specific decay time X(Mm) in storage means (S).

14. A system according to claim 11, where the system comprises a total of M microphones, where M is at least 1, and a total of N loudspeakers, where N is at least 1, where the system for each microphone-loudspeaker combination (m, n) based on said specific decay times or reverberation times X(Mm) determines an average decay time or reverberation time Y(f) as a function of frequency, based on which average decay time or reverberation time Y(f) said correction curve C is determined.

15. A system according to claim 14, where said average decay time or reverberation time Y(f) is processed by a weight function W(f) prior to being used for determining the correction curve C.

16. A system according to claim 14, where said correction curve C is calculated by the following expressions:
Y(f)=Σ(X(Mm)/M(N−1)
where X(Mm) is the specific decay or reverberation time as a function of frequency for each microphone, M is the total number of microphones and N is the total number of loudspeakers;
C1(f)=Y(f)/(W(f)+O)
where W(f) is a weight function and O is the average value of Y; and
C(f)=g(1/C1(f))
where g is a gain factor.

17. A system according to claim 14, where said correction curve C is calculated by the following expressions:
Y(f)=Σ(X(Mm)/MN
where X(Mm) is the specific decay or reverberation time as a function of frequency for each microphone, M is the total number of microphones and N is the total number of loudspeakers;
C1(f)=Y(f)/(W(f)+O)
where W(f) is a weight function and O is the average value of Y; and
C(f)=g(1/C1(f))
where g is a gain factor.

18. A system according to any of the preceding claims 11 to 17, where M≠N

19. An audio reproduction system comprising correction filter means for receiving an audio signal (49, 54, 61) and providing adjusted or corrected output signals to one or more loudspeakers (51, 56, 57, 64, 65), where said correction filter means has a filter curve C determined by the method according to any of the preceding claims 1 to 10 or by the system according to any of the preceding claims 11 to 18.

20. An audio reproduction system according to claim 19, where said adjusted or corrected output signals from said correction filter means are provided to one or more gradient loudspeaker systems (56, 64) and where said audio signal is provided to one or more conventional loudspeaker systems (57, 65).

21. An audio reproduction system according to claim 19 comprising a plurality of correction filter means (62, 63) each providing adjusted or corrected output signals, where adjusted or corrected output signals from at least one of said correction filter means (62) is provided to one or more gradient loudspeaker systems (64) and where adjusted or corrected output signals from at least one other of said correction filter means (63) is provided to one or more conventional loudspeaker systems (65).
